(19) United States
(12) Patent Application Publication
(10) Pub. No.: US 2008/0283112 A1
(43) Pub. Date: Nov. 20, 2008

(54) SOLAR ARRAY SUPPORT METHODS AND SYSTEMS

(76) Inventor: Steven J. Conger, Carbondale, CO (US)

Correspondence Address: SHERIDAN ROSS PC, 1560 BROADWAY, SUITE 1200, DENVER, CO, 80202, US

(21) Appl. No.: 12/122,228

(22) Filed: May 16, 2008

Related U.S. Application Data
(63) Continuation-in-part of application No. 11/856,521, filed on Sep. 17, 2007.
Application No. 11/856,521 is a continuation of application No. 10/606,204, filed on Jun. 25, 2003, now Pat. No. 7,285,719.
(60) Provisional application No. 60/459,711, filed on Apr. 2, 2003.

(51) Int. Cl. H01L 31/042

(52) U.S. Cl. 136/244

(57) ABSTRACT

Systems and methods for disposing and supporting a solar panel array are disclosed. In one embodiment, a system for supporting a solar panel array includes the use of support columns and cables suspended between the support columns, with the solar panels received by solar panel receivers that are adapted to couple to the cables. The solar panel array may then be used to provide power as well as shelter. Cooling, lighting, security, or other devices may be added to the solar panel array.

### CROSS REFERENCE TO RELATED APPLICATIONS

This application is a continuation-in-part application of U.S. application Ser. No. 11/856,521, filed on Sep. 17, 2007, which is a continuation application of U.S. application Ser. No. 10/606,204, filed Jun. 25, 2003, now the U.S. Pat. No. 7,285,719, which claims priority from Provisional Application Ser. No. 60/459,711, filed Apr. 2,2003, entitled “SOLAR SCULPTURE ENERGY AND UTILITY ARRAY” each prior application being incorporated herein by reference.

### FIELD OF THE INVENTION

The present invention is related to the field of solar energy capture, and more particularly, to devices, systems and methods relating solar energy capture.

### BACKGROUND OF THE INVENTION

Present systems for supporting solar panels tend to be bulky and expensive. Given the size and weight of such systems, implementation of solar panel arrays in remote locations is difficult and expensive. When large equipment is required, installation of a solar panel array in an environmentally sensitive area without significant impact on surrounding habitat becomes very difficult. Typically, such support systems do not allow for secondary uses of the solar panel arrays.

### SUMMARY OF THE INVENTION

The present invention, in an illustrative embodiment, includes a system for supporting a solar panel array. The system includes two pairs of vertical columns, where each pair includes a tall column and a short column. The pairs are placed a distance apart, and a first support cable is secured between the short columns and a second support cable is secured between the tall columns. A guy wire or other anchoring devices may be attached to the columns to provide lateral support to the columns against the tension created by suspending the support cables between the spaced columns. The system further includes a solar panel receiver adapted to be secured to the two support cables. The solar panel receiver may be adapted to receive any type of solar panel or several panels. The receiver may include a maintenance catwalk or other access providing design element.

In another illustrative embodiment, the present invention includes a system for providing both shelter and electricity. The system may again include columns, support cables, and one or more solar panel receivers as in the illustrative solar panel array support system noted above. The system further includes a number of solar panels secured to or received by the solar panel receiver. The columns may be sized to allow an activity to occur beneath the solar panel receivers. For example, if the desired activity is that of providing a shaded parking lot, the columns may have a height allowing vehicles to be parked beneath the solar panel receivers, and the columns may be spaced apart to create a sheltered area sized to correspond to the desired area of the parking lot. In yet another illustrative embodiment, the present invention includes a system for supporting a solar panel array, the system comprising four anchor points, with a first support cable suspended between a first pair of anchor points, and a second support cable suspended between a second pair of anchor points. The system further includes a solar panel receiver adapted to be supported by the first and second support cables, the solar panel receiver also adapted to receive one or more solar panels.

In a further embodiment, the present invention includes methods of supporting a solar panel array. The methods include the step of using cables to support solar panel receivers adapted to receive one or more solar panels. In yet another embodiment, the present invention includes a method of creating a sheltered space which makes use of a solar panel array that creates electricity, where the method also includes using the electricity to cool an area beneath the array.

In other embodiments, the present invention includes systems comprising various combinations of support cables, anchor lines, anchors, and support columns.

### BRIEF DESCRIPTION OF THE DRAWINGS

FIG. 1 is a perspective view of a solar panel array supported in accordance to an illustrative embodiment;

FIG. 2 is a longitudinal section view of a solar panel array supported in accordance to an illustrative embodiment;

FIG. 3 is a horizontal section view of a solar panel array supported in accordance to an illustrative embodiment;

FIG. 4 is a perspective rear view of an illustrative solar panel array;

FIG. 5 is a perspective side view of an illustrative solar panel array;

FIG. 6 is a rear perspective view of an illustrative pod showing the use of several struts and cords to create a rigid member;

FIG. 7 is a section view of an illustrative pod including several optional features;

FIG. 8 is a front perspective view of several solar panel receivers linked together;

FIG. 9 is a front elevation view of several solar panel receivers linked together;

FIG. 10 is a front and side perspective view of an illustrative solar panel array including a center support member;

FIG. 11 is a section view showing an illustrative solar panel array including a center support member;

FIG. 12 is a front elevation view of an illustrative solar panel array suspended across a valley;

FIG. 13 is an overhead plan view of an illustrative solar panel array suspended across a valley;

FIG. 14 is a perspective view of a solar panel array in accordance with another embodiment of the present invention;

FIG. 15 is a rear elevation view of the solar panel array illustrated in FIG. 14;

FIG. 16 is a side view of the solar panel array of FIG. 14;

FIG. 17 is a perspective view of a solar panel array in yet another embodiment of the present invention;

FIG. 18 is a rear elevation view of the embodiment of FIG. 17;

FIG. 19 is a perspective view of yet another solar panel array embodiment in accordance with the present invention;

FIG. 20 is a rear elevation view of the embodiment of FIG. 19;

FIG. 21 is an enlarged side view of the embodiment of FIG. 19;

FIG. 22 illustrates yet another solar panel array embodiment in accordance with the present invention;

FIG. 23 is a perspective view of a plurality of rows of solar panel arrays;

FIG. 24 is another perspective view of a plurality of rows of solar panel arrays;

FIG. 25 is a side view of a solar panel array in yet another embodiment of the present invention; and

FIG. 26 is an enlarged perspective view of another illustrative pod used to support a plurality of solar panels in the present invention.

### DETAILED DESCRIPTION

The following detailed description should be read with reference to the drawings. The drawings, which are not necessarily to scale, depict illustrative embodiments and are not intended to limit the scope of the invention.

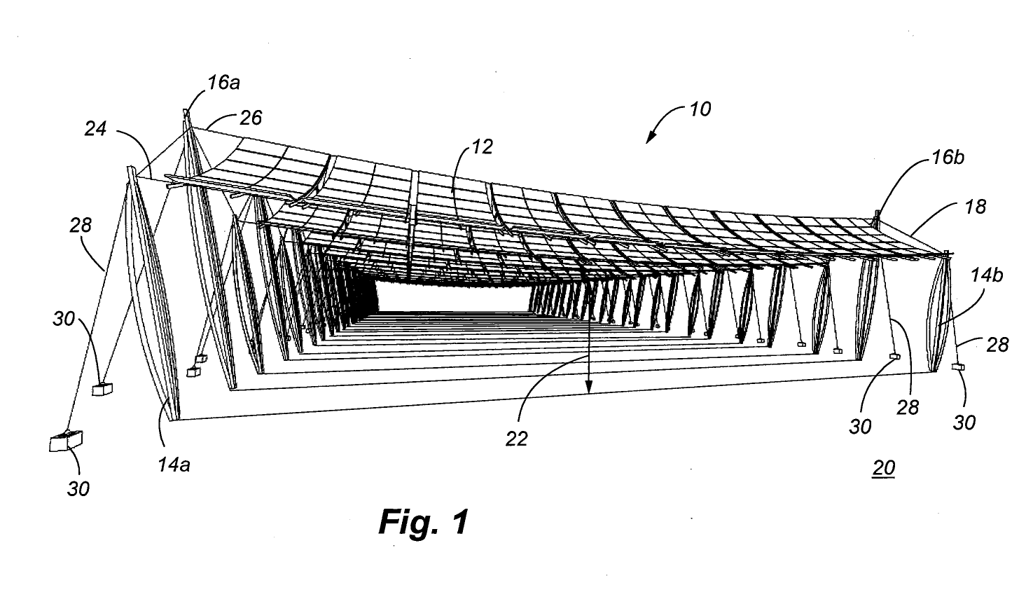

FIG. 1 is a perspective view of a solar panel array supported in accordance with an illustrative embodiment. A solar panel array 10 is illustrated as including a number of solar panel receivers 12. Pairs of short columns 14a, 14b and tall columns 16a, 16b are aligned with one another. The pairs of columns 14a, 16a and 14b, 16b may also be connected by a stability cable 18 that runs along the edges of the array 10. The solar panel receivers 12 are held above a surface 20 at a height 22 defined by the columns 14a, 14b, 16a, 16b. A first cable 24 is suspended between the short columns 14a, 14b, and a second cable 26 is suspended between the tall columns 16a, 16b. The solar panel receivers 12 are designed to be supported by the cables 24, 26, so that the overall design is a lightweight, flexible and strong solar panel array 10 that leaves plenty of usable, sheltered space below. Anchor lines 28 and anchors 30 may be used to provide further support and to enable the use of lightweight columns 14a, 14b, 16a, 16b.

The surface 20 may be, for example, a generally flat area of ground, a picnic area in a park, a parking lot, or a playground. The height 22 may be chosen to allow for a desired activity to occur beneath the array 10. For example, if a parking lot is beneath the array 10, the height 22 may be sufficient to allow typical cars and light trucks to be parked underneath the array 10, or the height may be higher to allow commercial trucks to be parked beneath the array 10. If a playground is beneath the array 10, the array 10 may have a height 22 chosen to allow installation of desired playground equipment.

Any suitable material and/or structure may be used for the columns 14a, 14b, 16a, 16b including, for example, concrete or metal, or a simple pole or a more complicated trussed column. In some embodiments a footing may be placed beneath the base of each of the columns 14a, 14b, 16a, 16b to provide stability on relatively soft ground. The cables 18, 24, 26 and anchor lines 28 may be made of any material and design as well including, for example, metals, composites, and/or polymeric fibers. In one embodiment the primary material used in the columns 14a, 14b, 16a, 16b, the cables 24, 26 and the anchor lines 28 is steel. Because the primary support technology for the array 10 is the cables 24, 26 under tension, the design is both visually and literally lightweight.

While FIG. 1 illustrates an embodiment wherein the columns 14a, 14b, 16a, 16b are either “short” or “tall”, in other embodiments the columns may all be of the same height. No particular angle of elevation is required by the present invention, however, it is contemplated that, depending upon the latitude, time of year, and perhaps other factors, certain angles may be more effective in capturing incident sunlight.

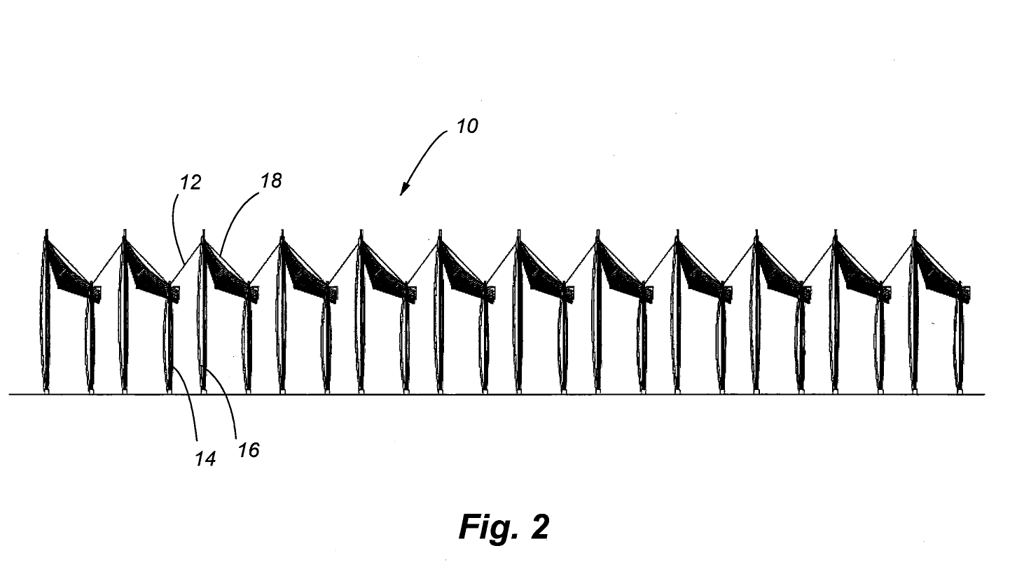

FIG. 2 is a longitudinal section view of a solar panel array supported in accordance with an illustrative embodiment. The array 10 illustrates the relative spacing of rows of the array 10, and helps to show how the stability cable 18 connects the columns 14, 16 of the array 10. The stability cable 18 may be coupled to an anchor member as well, though this is not shown in FIG. 2. It can be seen that the relative heights of the columns 14, 16 help to define the angle that the solar panel receivers 12 have with respect to the incident sunlight. In some embodiments, the columns 14, 16 or the solar panel receivers 12 may include a mechanism allowing for adjustment of the angle of the solar panel receivers 12. To do so, for example, the length of the columns 14, 16 may be adjusted, or the solar panel receivers 12 may include a mechanism for changing the angle of individual panels or entire receivers 12. For example, with the changing of seasons, the height of the sun in the sky may vary sufficiently to affect the efficiency of the solar panel receivers 12, and so it may be desirable to vary the angle of the receivers 12. Also, as the sun moves during the day it may be desirable to change the angle of the receivers 12 to improve light reception.

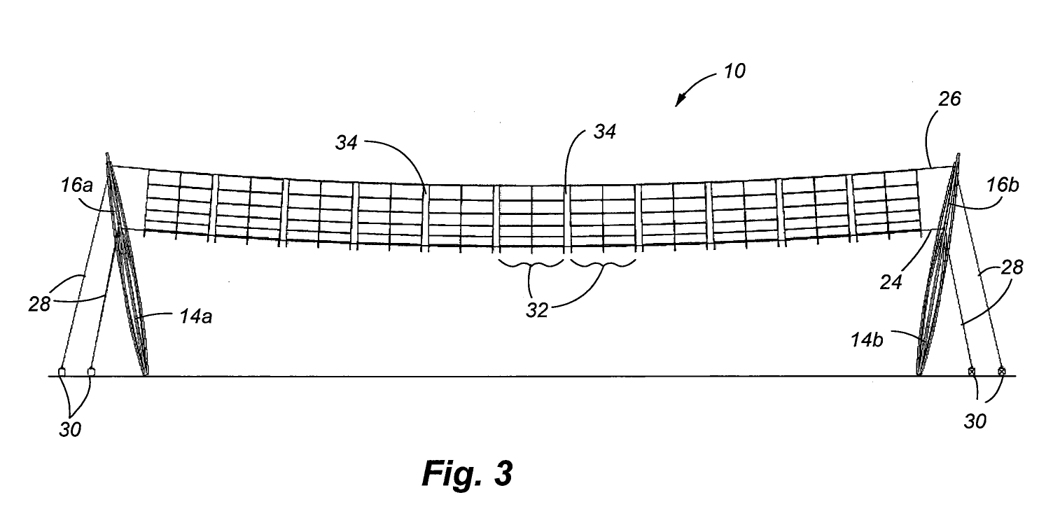

FIG. 3 is a horizontal section view of a solar panel array supported in accordance with an illustrative embodiment. As illustrated, the array 10 is supported by short columns 14a, 14b, tall columns 16a, 16b, and cables 24, 26. Anchor lines 28 and anchors 30 are provided to improve stability and allow the use of lightweight columns 14a, 14b, 16a, 16b. The solar panel receivers 12 are illustrated as pairs of individual units 32 having gaps 34 between each unit 32. The gaps 34 allow for air movement, reducing the amount of wind resistance of the array 10. The gaps 34 also allow for relative movement of the units 32 since the cables 24, 26 are somewhat flexible.

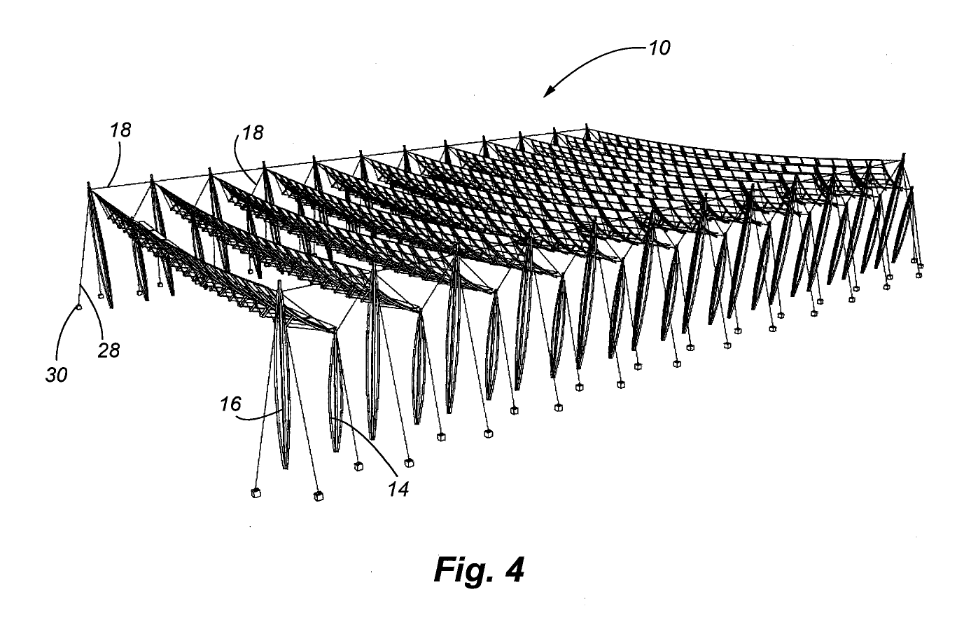

FIG. 4 is a perspective rear view of an illustrative solar panel array. It can be seen that the stability cables 18 are coupled in various configurations along the length of the array 10, linking the short columns 14 and tall columns 16 to create a linked structure. The array 10 also includes various anchor cables 28 and anchor points 30, including at the end of the array 10 that may help anchor the stability cables 18.

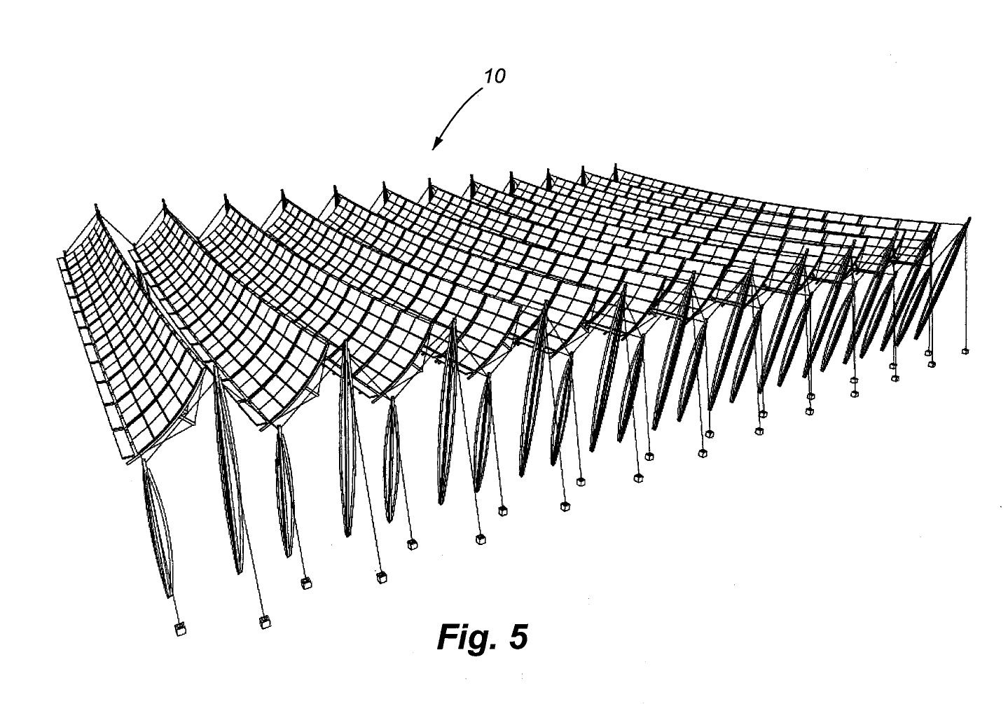

FIG. 5 is a perspective side view of an illustrative solar panel array 10 which is similar to that shown in FIGS. 1-4. It can be appreciated from the several views of FIGS. 1-5 that the illustrative array 10 provides a readily usable shelter that is amenable to a variety of activities.

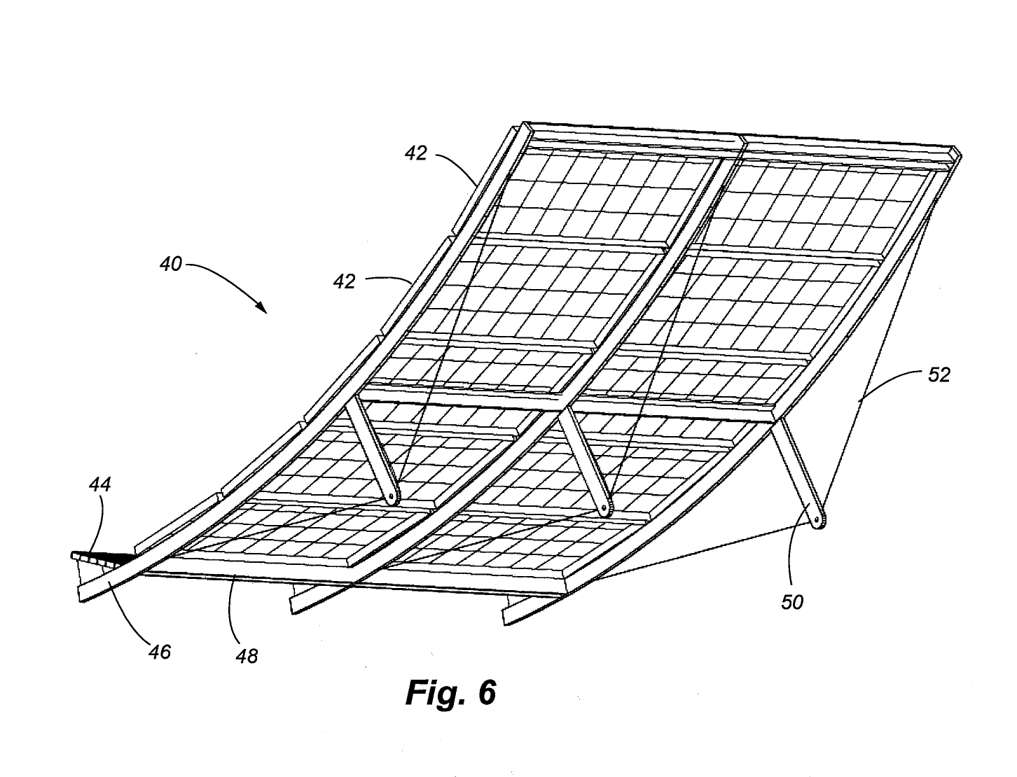

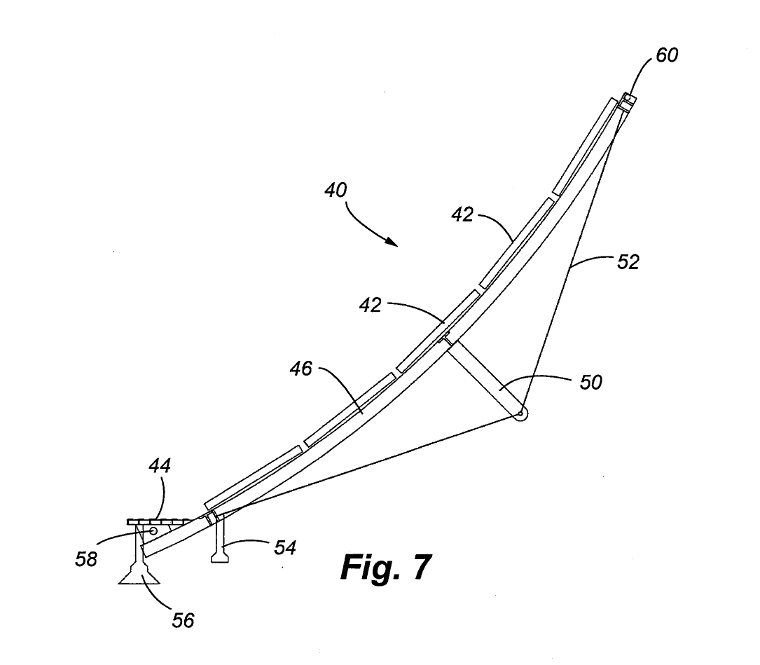

FIGS. 6 and 7 illustrate a pod which may be used as a solar panel receiver. The “pods” illustrated herein are intended to provide an example of a solar panel receiver that may be used with the present invention. The solar panel receiver may, of course, have a variety of other structures to perform its function of holding one or more solar panels while being adapted to couple to support cables as illustrated herein.

FIG. 6 is a rear perspective view of an illustrative pod showing the use of several struts and cords to create a rigid member. The pod 40 is shown with several solar panels 42 which may be, for example, photovoltaic panels. A maintenance walkway 44 is included as an optional feature of the pod 40. Several curved struts 46 extend vertically along the back of the pod 40, with several horizontal struts 48 coupled by moment connections to the curved struts 46. By using moment connections, the overall structure becomes a rigid yet lightweight frame for receiving the solar panels 42. A center strut 50 extends out of the back of the pod 40, and is connected to a truss cable 52 which provides another lightweight yet highly supportive aspect of the structure. The center strut 50 and truss cable 52 allow a lightweight curved strut 46 to be used, lending support to the center of the curved strut 46.

In another embodiment, rather than creating electricity with photovoltaic panels, the present invention may also be used to support solar panels that collect solar thermal energy. The solar thermal collectors could be mounted on the solar panel receivers illustrated herein, and thermal energy could be collected by the use of a heat transfer medium pumped through flexible tubing. In one such embodiment, glycol may be used as a mobile heat transfer medium, though any suitable material may be used.

FIG. 7 is a section view of an illustrative pod including several optional features. The pod 40 is shown with solar panels 42 in place. The optional maintenance walkway 44 is again shown on the lower portion of the curved member 46. The center strut 50 and truss cable 52 again provide support to the curved member 46. The pod 40 may include, for example, a mister 54 that can be used to provide evaporative cooling to the sheltered area beneath a solar array using the pod 40. The pod 40 may also include a light 56 or security camera, for example. In one embodiment, a solar array may be used to provide a parking shelter, with the solar array storing electricity during the day using, for example, fuel cells or batteries, and then discharging the stored electricity by lighting the shelter created by the solar array during the evening.

Two cable receivers 58, 60 are also illustrated. While shown in the form of a simple opening that a cable may pass through, the cable receivers 58, 60 may take on a number of other forms. For example, the cable receivers 58, 60 may include a mechanism for releasably locking onto a cable. It can be appreciated from FIGS. 6 and 7 that the illustrative pod 40 is designed so that rain is readily directed off of the solar panels, as the water will run down the curve of the pod 40. In other embodiments, the pod 40 may be more or less flat, rather than having the curvature shown, or may have a different curvature than that shown.

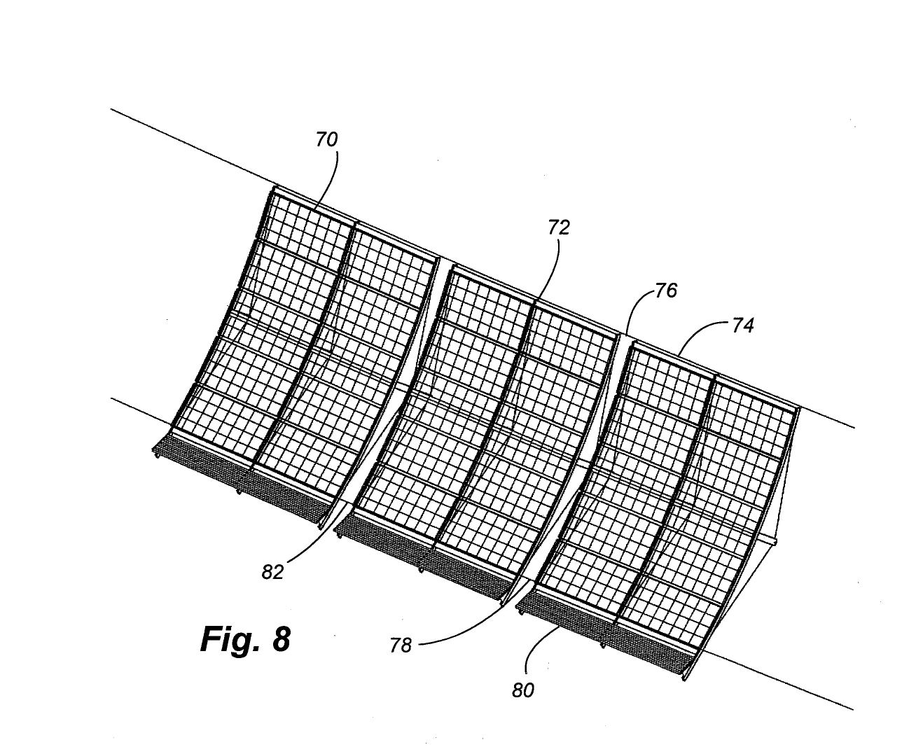

FIG. 8 is a perspective front view of several solar panel receivers linked together. A first solar panel receiver 70, a second solar panel receiver 72, and a third solar panel receiver 74 are supported by an upper support cable 76 and a lower support cable 78. An optional maintenance walkway 80 is illustrated as well. Also included is a flexible electric cable 82 that allows for transmission of electrical power from each of the solar panel receivers 70, 72, 74 when solar energy is captured. The flexible electric cable 82 may also serve to distribute power to devices such as security cameras or lighting that may be provided beneath the solar panel receivers 70, 72, 74.

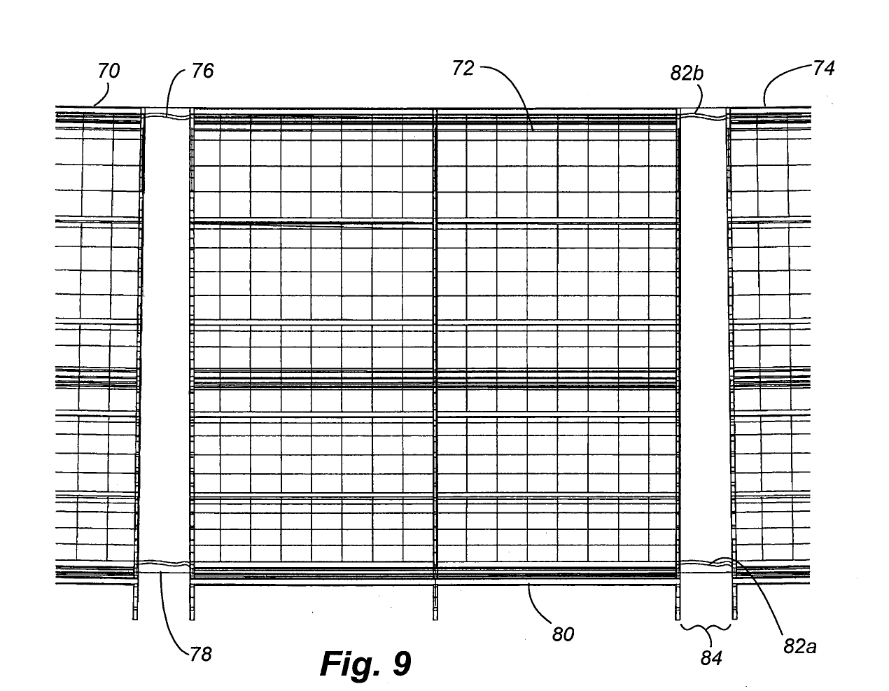

FIG. 9 is a front elevation view of several solar panel receivers linked together. Again, the solar panel receivers 70, 72, 74 are shown supported by an upper support cable 76 and a lower support cable 78, and include an optional maintenance walkway 80. Two flexible electric cables 82a, 82b are illustrated in FIG. 9, and may serve the same purposes as that noted above with respect to FIG. 8. It is clearly shown in FIG. 9 that there is a gap 84 between the solar panel receivers 70, 72, 74. The gap 84 allows the solar panel receivers 70, 72, 74 to move independently, rendering the overall array less rigid and more likely to withstand high winds. The gap 84 also prevents neighboring solar panel receivers (i.e. 70 and 72 or 74 and 74) from damaging one another in windy conditions.

Depending on the desired output of the array, the flexible electric cables 82a, 82b may be coupled to a substation for gathering produced power and providing an output. For example, the electricity gathered is inherently direct current power, an array as illustrated herein may be easily used to charge batteries or fuel cells. The power may also be used with an electrolyzer to produce hydrogen and oxygen, with the hydrogen available for use as a fuel.

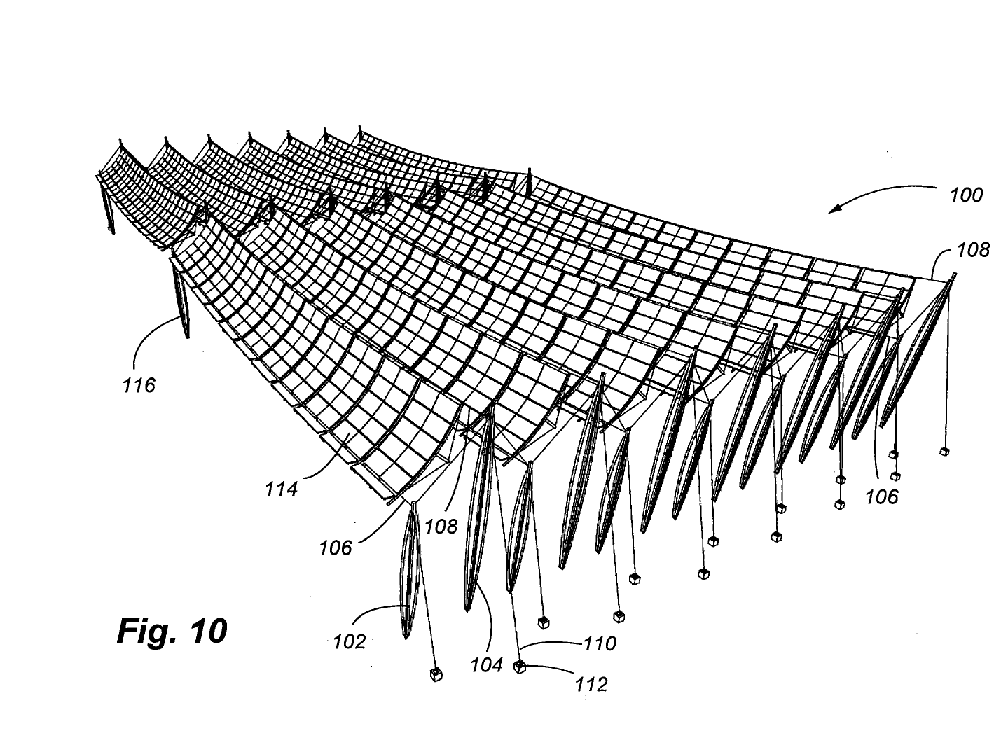

FIG. 10 is a perspective front and side view of an illustrative solar panel array including a center support member. The illustrative array 100 includes a number of alternating short columns 102 and tall columns 104, with support cables 106, 108 suspended from the columns 102, 104. Anchor lines 110 and anchors 112 provide additional support, and the array 100 supports a number of solar panel receivers 114. The further addition in FIG. 10 is the inclusion of a center support 116, which allows for a longer span to be covered between the outer columns 102, 104, reducing the need to place additional anchors 112. Further, because the center support 116 does not have to provide stability against lateral movement, and only needs to provide vertical support, the center support 116 may be of an even lighter weight construction than the outer columns 102, 104.

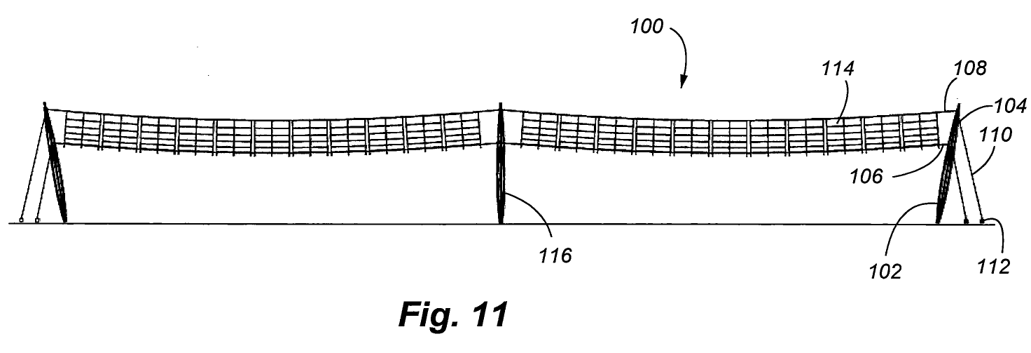

FIG. 11 is a section view showing an illustrative solar panel array including a center support member. Again, the array 100 is supported by the use of a short column 102, a tall column 104, a lower support cable 106 and an upper support cable 108. The array 100 is stabilized in part by the use of anchor lines 110 and anchors 112, and a number of solar panel receivers 114 are supported. The center column 116 provides a central support, but is not required to add to the lateral stability of the array 100, because there are portions of the array pulling equally on both sides of the center column 116.

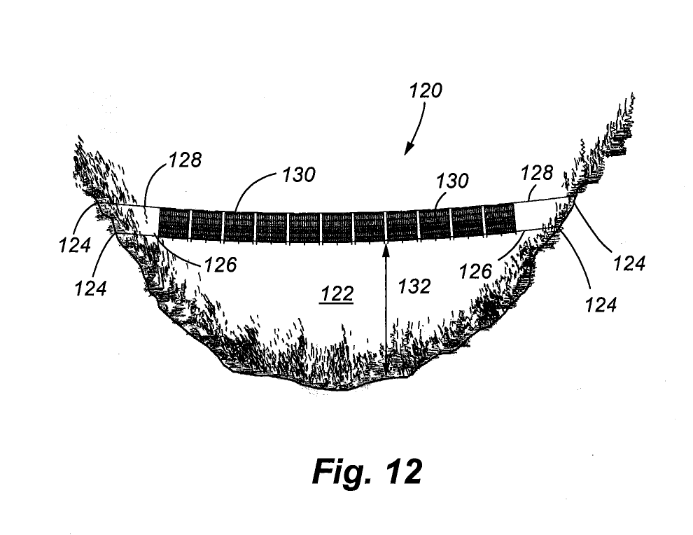

FIG. 12 is a front elevation view of an illustrative solar panel array suspended across a valley. An array 120 is suspended across a valley 122 by the use of four anchors 124 that enable two support cables 126, 128 to be suspended across the valley 122. A number of solar panel receivers 130 are supported by the support cables 126, 128. By suspending the array 120 across the valley 122, a desired height 132 above the valley floor can be achieved by the array. The height 132 may be sufficient to allow wildlife to pass below.

A number of potential environmental benefits of this type of structure can be identified, including that the structure provides a quiet and safe energy production array, the structure provides shade and/or shelter, and the structure can be installed without requiring a large amount of heavy machinery. The use of an array over eroding ground may encourage foliage growth in highly exposed locations, slowing erosion.

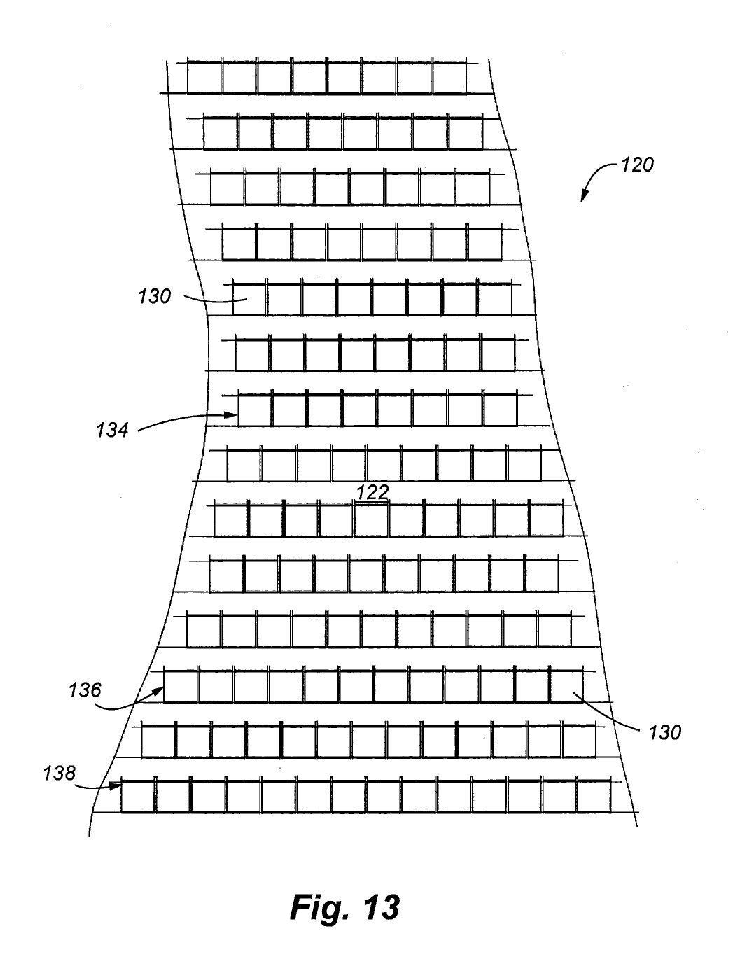

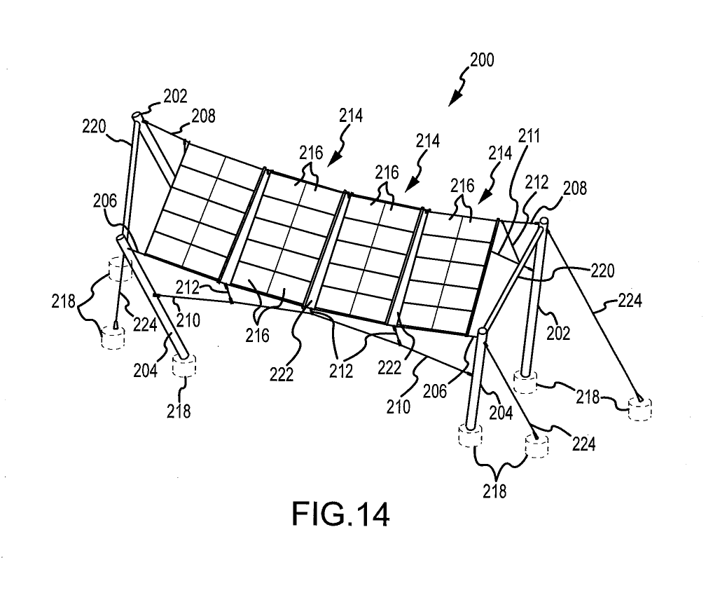

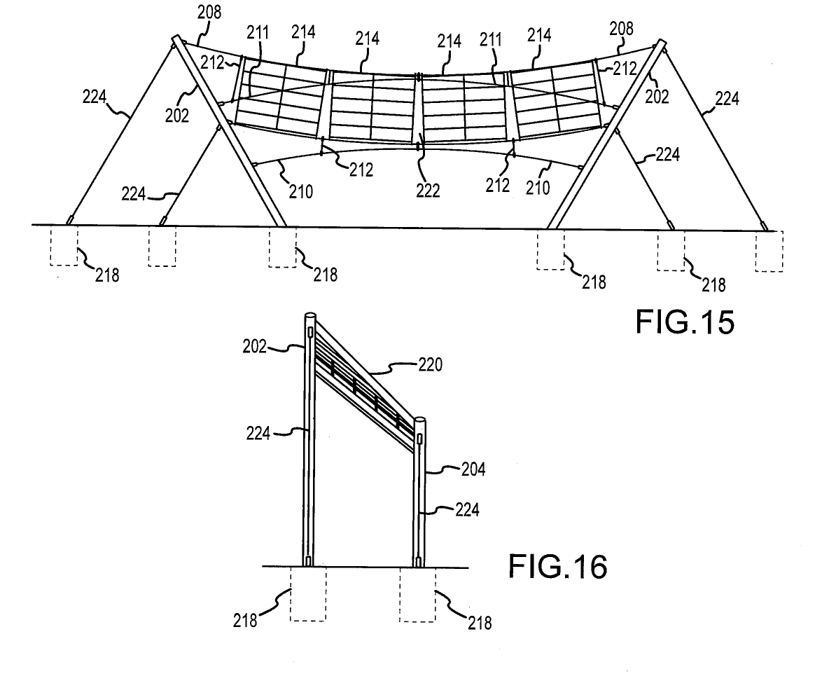

FIG. 13 is an overhead plan view of an illustrative solar panel array suspended across a valley. It can be seen that the array 120 is designed to match the shape of the valley 122. In particular, the array 120 includes a number of individual lines of solar panel receivers 130. By varying the number of solar panel receivers 130 suspended by each pair of support cables, a relatively short line 134 can match a relatively narrow place in the valley 122, while longer lines 136, 138 span a wider portion of the valley 122. FIGS. 14-16 illustrate yet another preferred embodiment of the present invention, in the form of a solar panel array 200 comprising a plurality of receivers or pods 214 supported by another arrangement of cables and columns. More specifically, FIGS. 14 and 15 illustrate a plurality of spaced pods 214 each containing a number of solar panels 216, a first cable 206 supporting one end of the pods, and a second cable 208 supporting an opposite end of the pods. First cable 206 is strung between short columns 204, while second cable 208 is strung between tall columns 202. A pair of complementary support cables is also provided to further support the pods 214, namely, a front complementary support cable 210 and a rear complementary support cable 211. A number of vertically oriented connecting cables 212 interconnect the complementary support cables 210 and 211 to their corresponding first and second cables 206 and 208. The embodiment of FIGS. 14-16 also includes cross-supports 220 that extend between the columns 202 and 204. Members 202, 204, and 220 may be metallic and made of material such as steel or aluminum, and these members may be configured as I-beams, channels, tubular members, and others. The gaps 222 provided between the pods 214 allow wind to pass between the pods to therefore prevent damage to the system during high wind conditions. Anchor lines 224 extend from each of the columns to respective anchors 218. It shall be understood that additional anchor lines 224 can be added to provide the necessary support to the columns. FIG. 15 is a rear elevation of the embodiment of FIG. 14, better illustrating the complementary support cables 210 and 211. The side view of FIG. 16 also illustrates that the anchor lines 224 may be placed in-line with the columns to minimize the side profile of the system. FIGS. 41-16 also show a number of other geometrical features defining the construction and overall appearance of the system. For example, the complementary support cables are coplanar with their corresponding first/second cables. The panel receivers have a first end residing at a first height, and a second end residing at a second lower height. Thee panel receivers are substantially rectangular shaped and evenly spaced from one another along the first and second cables. The first cable defines a first curvature, the second cable defines a second curvature extending substantially parallel to the first curvature. The complementary support cables have an opposite curvature as compared to the first and second cables, and the complementary support cables also extend substantially parallel to one another. The gaps between each panel are substantially triangular shaped such that the portions of the gaps located adjacent the second cable are smaller than the portions of the gaps located adjacent the first cable.

As also shown in the FIGS. 15 and 16, the columns 202 and 204 extend at an angle from the mounting surface such that the upper ends of the columns are further apart from one another as compared to the lower ends of the columns. Depending upon the location where the solar panel array is to be installed, it may be necessary to adjust the location of the columns in order to take advantage of available ground space and to maximize the area to be covered by the solar panel array. For example, if the solar panel array is used to cover a parking lot, it may be necessary to adjust the location of the columns based upon available space in the parking lot, yet maximizing the overall area covered by the solar panels by the non-vertical columns. Thus, in the embodiment of FIGS. 14-16, the group of pods can extend over a greater overall area as opposed to use of vertical columns anchored at the same column locations Additionally, there may also be some aesthetic benefits achieved in arranging the columns in various combinations of both vertical and angular extensions from the mounting surface.

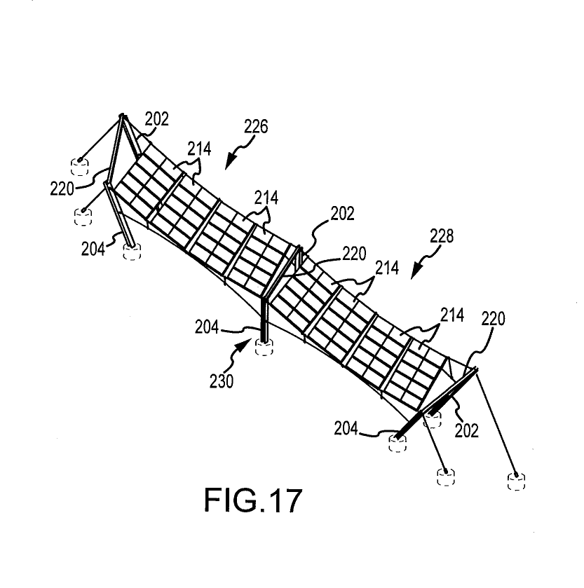

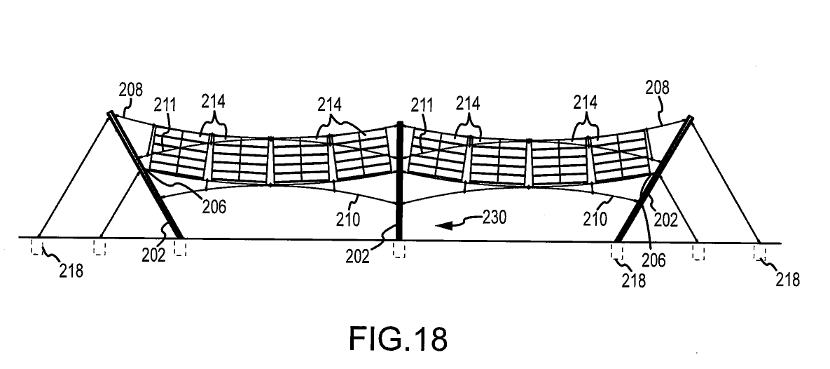

FIG. 17 illustrates yet another embodiment of the present invention. In this embodiment, an intermediate support 230 is provided that extends vertically from the ground, while the outside or exterior columns extend at an angle, like those illustrated in FIG. 15. In this embodiment, the pods or receivers can also be defined as corresponding to a first group 226 and a second group 228. In the first group, the pods extend between one of the exterior column pairs and the intermediate support 230, while the other group 228 of pods extends between the opposite exterior column pair and the intermediate support 230. FIG. 18 is a rear elevation view of the embodiment of FIG. 17, further disclosing particular details of this embodiment to include the complementary support cables 210 and 211.

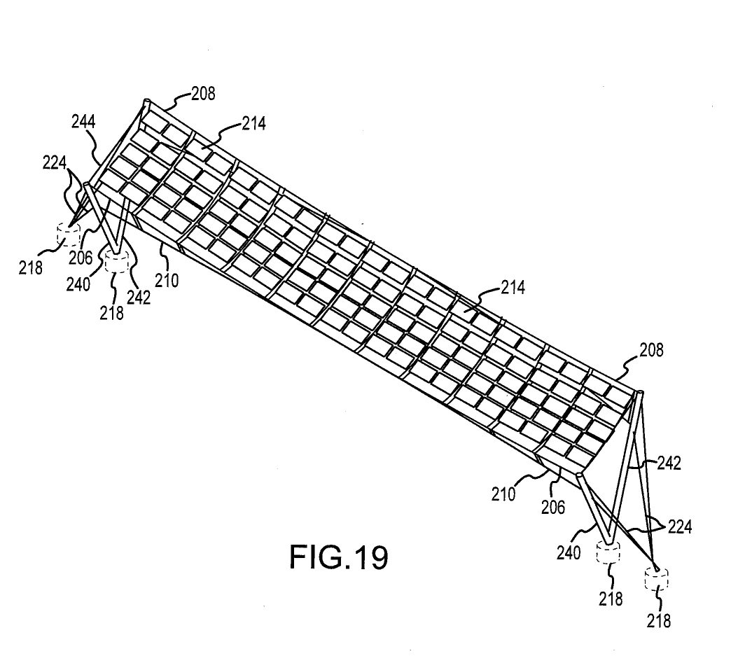

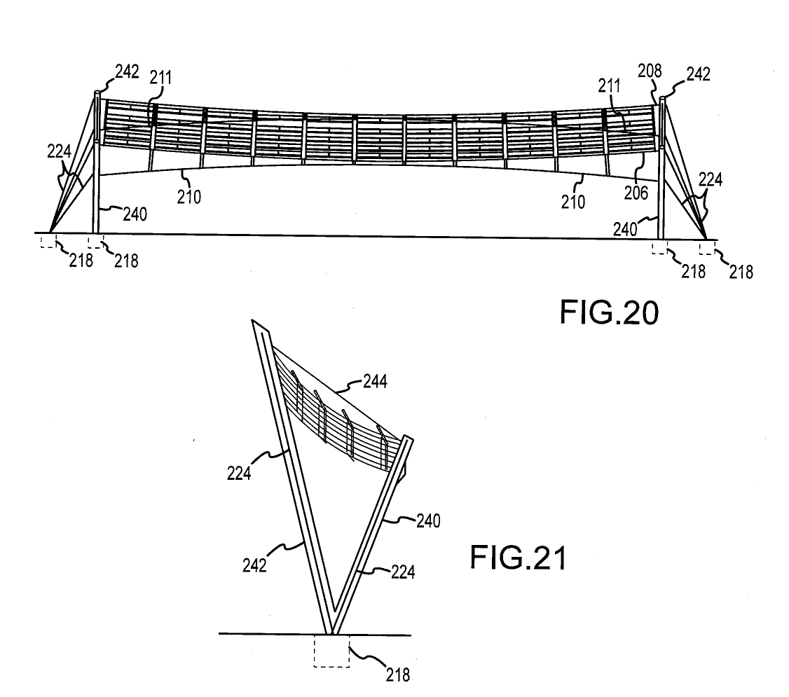

FIG. 19 illustrates yet another preferred embodiment of the present invention. In this embodiment, in lieu of single columns that are secured to the mounting surface, the columns 240 and 242 are arranged in a V-shaped configuration. The lower ends of the columns 240 and 242 are anchored at the same location while the upper ends of the columns 240 and 242 diverge from one another. As with each of the previous embodiments, the V-configured columns 240 and 242 may be made of tubular members or other types of metallic members. As also shown, the anchor lines 224 for each pair of the V-configured columns may be oriented so that there is a single anchor point 218 from which the anchor lines extend. Referring to FIG. 20, a rear elevation view is provided of the embodiment of FIG. 19. This Figure also shows the manner in which the various anchor lines 224 for each column pair terminate at a common anchor point 218. FIG. 21 illustrates the manner in which the anchor lines 224 may extend in a V-shaped configuration to match the columns 240 and 242 and thus minimizing the side profile of the system. Additionally, in this embodiment a stabilizing cable 244 may be provided that extends between the upper ends of the column pairs.

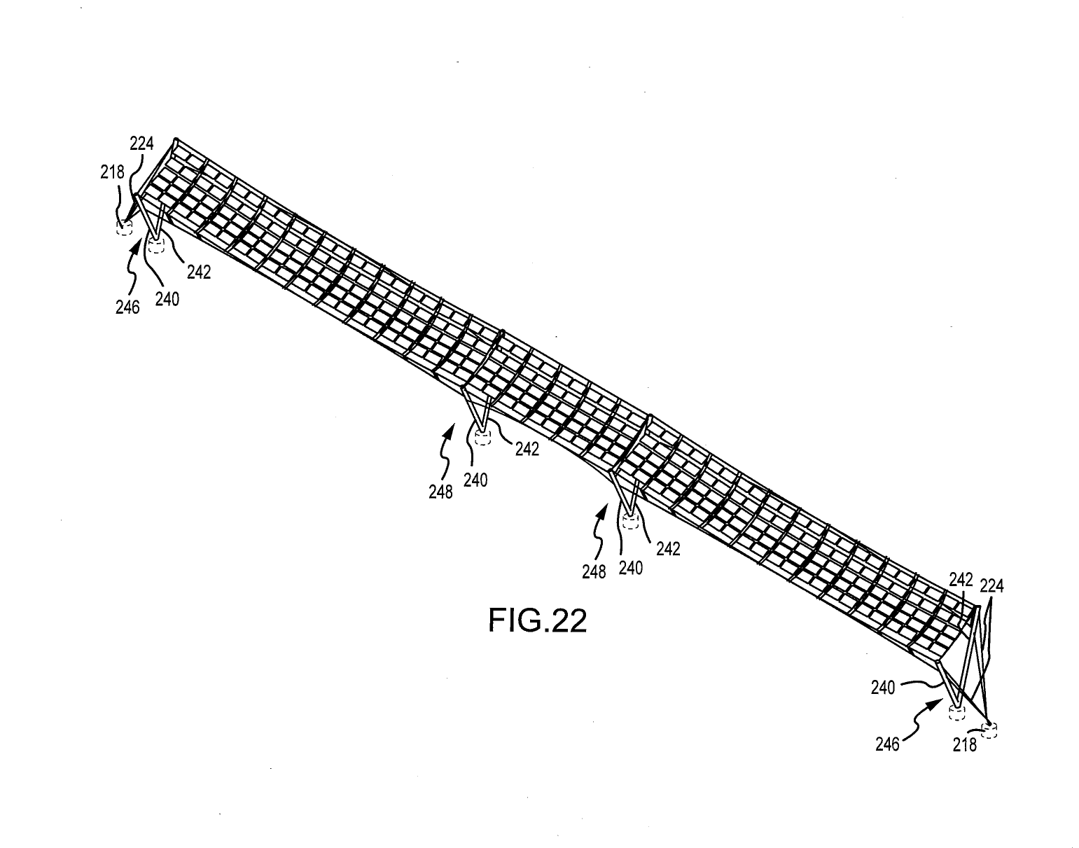

FIG. 22 illustrates yet another preferred embodiment of the present invention, wherein the V-shaped column supports 240 and 242 are utilized in an extended row of pods 214. More specifically, a pair of outside or end columns 246 are provided along with a pair of intermediate columns 248. Based upon the required length of the row, the necessary combination of intermediate column supports can be provided for adequate structural support.

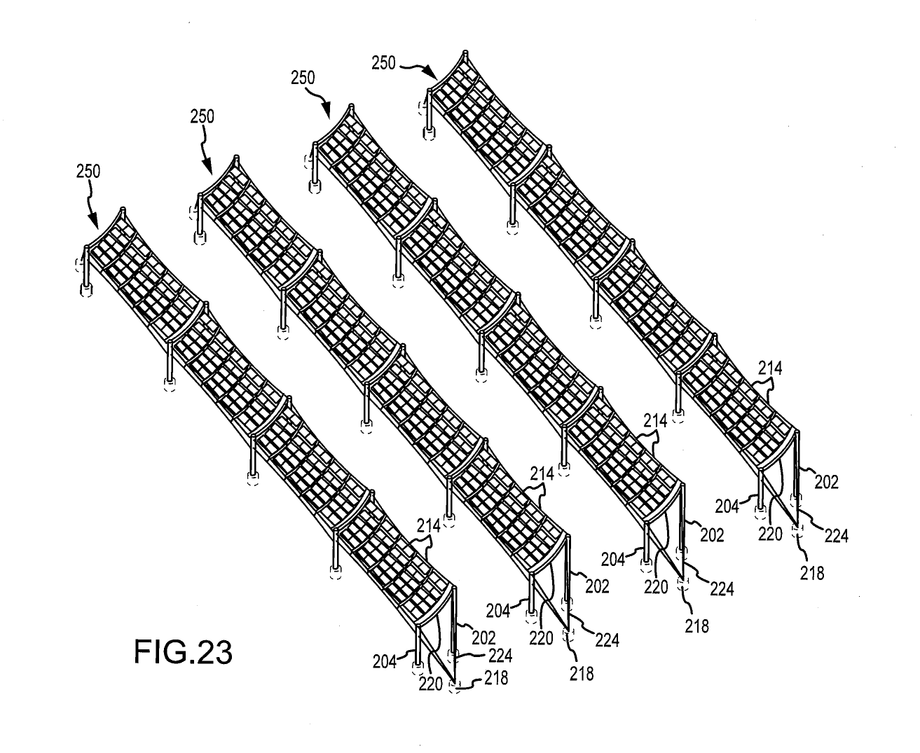

Referring to FIG. 23, yet another embodiment of the present invention is illustrated comprising a plurality of rows 250 of solar panel arrays and wherein the column supports 202 and 204 extend substantially vertically from the mounting surface. In this embodiment, it is noted that the anchor lines 224 for each column pair extend to a common anchor point 218. The rows 250 may be selectively spaced from one another to provide the optimal area coverage for the solar panel arrays, as well as optimal shade in the event the arrays are used to cover a structure such as a parking lot. Thus, it shall be understood that the rows 250 may be either spaced more closely to one another, or farther apart depending upon the particular purpose of installation.

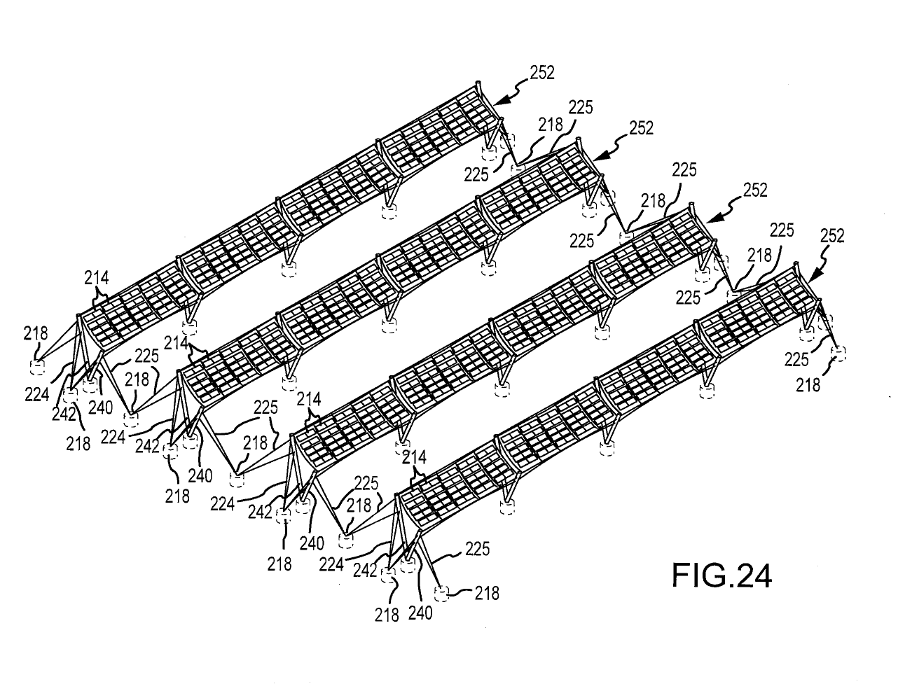

FIG. 24 illustrates yet another preferred embodiment of the present invention, showing a plurality of rows 252 of solar panel arrays wherein the V-column configuration is used with column supports 240 and 242. As with the embodiment shown in FIG. 23, the rows 252 may be either spaced more closely to one another, or farther apart depending upon the particular purpose of installation. FIG. 24 also illustrates some additional anchor lines 225 that are used to further stabilize the rows 252 of solar panel arrays. These anchor lines 225 are particularly advantageous in handling laterally directed forces, such as wind.

With each of the embodiments of the present invention, it shall be understood that the particular height at which the solar panels are located can be selectively adjusted for the particular purpose of installation.

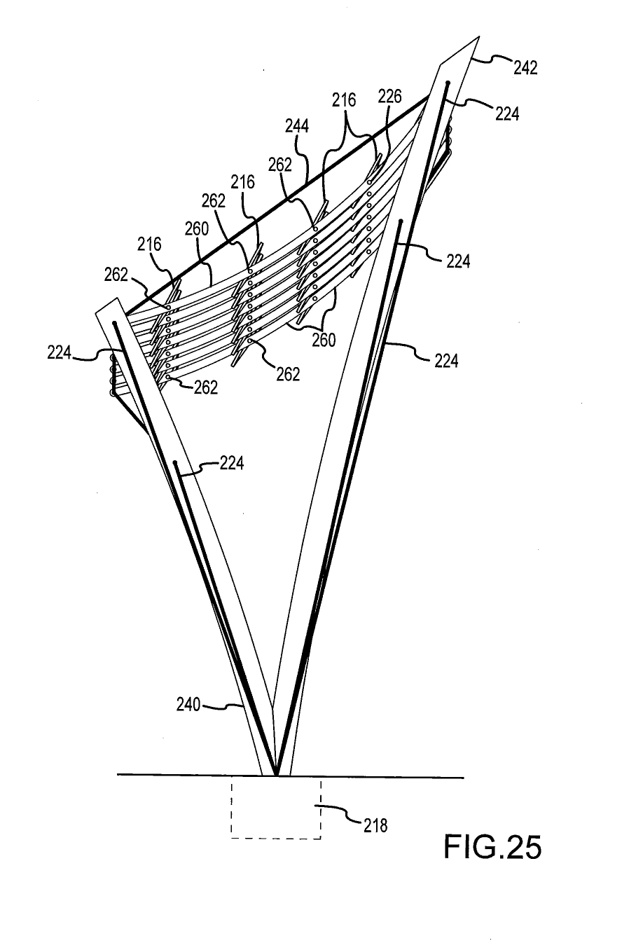

FIG. 25 illustrates yet another preferred embodiment of the present invention, wherein each of the solar panels 216 may be rotatably mounted to their corresponding supporting pod or receiver. As shown, the embodiment of FIG. 25 incorporates curved struts 260 and pivot mounts 262 that enable each of the solar panels 216 to be disposed at a desired angle with respect to the sun. The pivot mounts 262 can take a number of forms. For example, a pivot mount 262 could include a continuous rod that extends horizontally across the corresponding pod or receiver and which is secured to an overlying solar panel 216. The rod is then rotatably mounted within the receiver such that the solar panel 216 can be grasped and rotated to the desired inclination with respect to an optimal sun-capturing orientation.

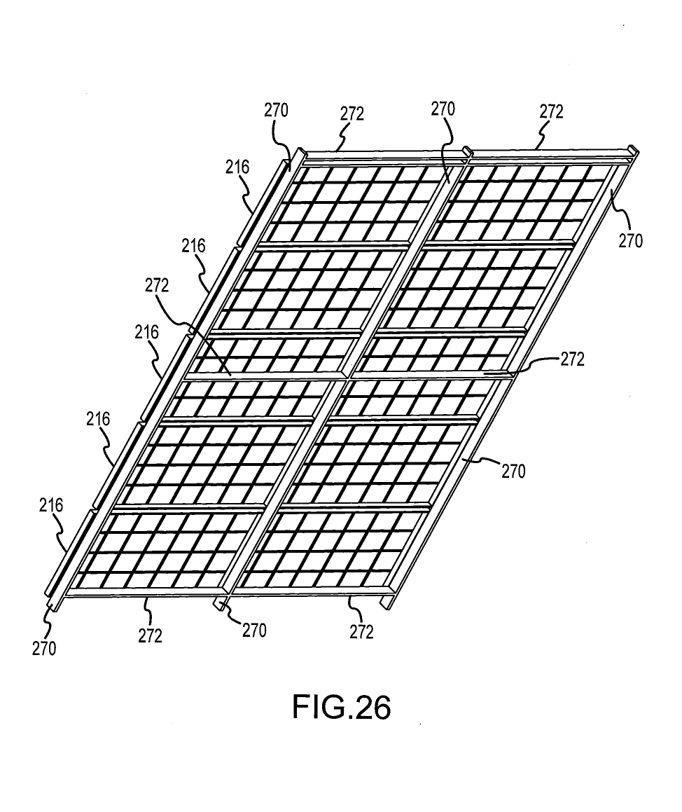

FIG. 26 illustrates a pod or receiver that may incorporate a group of linear or straight struts. As shown, a plurality of first struts 270, and a plurality of second orthogonally oriented struts 272 are provided to support the solar panels 216 mounted to the pod. The receiver shown in FIG. 26 supports a group of ten solar panels 216 arranged in a 2 by 5 matrix. A width of the pod may be defined as the distance between the most outer or exterior struts 270, and a height of the pod may be defined as the distance between the most outer or exterior second struts 272. The spacing of the pods when mounted to the cables depends on a number of factors to such as the weight of the pods and panels, wind conditions, snow loading conditions and others. In one aspect of the invention, spacing the pods with gaps between the pods that does not exceed the widths of the pods is acceptable for some installations.

It shall be understood that with respect to each of the preferred embodiments of the present invention, either pods having the curved or straight struts can be used. Additionally, it shall be appreciated that the number of solar panels mounted to each pod can be configured for the particular installation. Thus, the pods may contain more or fewer panels as compared to what is illustrated in the preferred embodiments.

For the illustrative pod shown in FIG. 26, cable receivers 58 and 60 may be incorporated thereon to allow the pod attach to the cables 206 and 208. As previously mentioned, while the cable receivers may be simply openings formed in the ends of the pods, the cable receivers may take another form such as a mechanism which selectively locks the pod onto the cable and therefore, allows a pod to be removed for maintenance or replacement. Accordingly, it shall be understood that the pods can be removed from the cables as necessary to either generate another different combination of pod arrangements, or to selectively replace/repair defective solar panels.

The flexible electric cables 82a and 82b may be incorporated in each of the embodiments of the present invention in order to allow each of the solar panel arrays to be coupled to a substation for gathering of produced power. As also mentioned, the solar panel arrays may be electrically coupled to sources of stored electric power such as batteries or fuel cells. Other arrangements of electrical cables may be used to most effectively transfer power from the solar panels to the power storage location or to a substation.

Those skilled in the art will recognize that the present invention may be manifested in a variety of forms other than the specific embodiments described and contemplated herein. Accordingly, departures in form and detail may be made without departing from the scope and spirit of the present invention as described in the appended claims.

What is claimed is:

1. A system for supporting a solar panel array, comprising:
two pairs of columns, each pair having a first column and a second column;
a first cable suspended between the first columns;
a second cable suspended between the second columns;
a plurality of panel receivers each having a plurality of solar panels mounted thereto, said plurality of panel receivers being secured to each of the two cables;
each of said panel receivers being spaced from one another by a gap; and
at least one complementary support cable spanning between one of said pairs of columns and connected to said first or second cable by plurality of connecting cables extending between said at least one complementary support cable and said first or second cable.

2. A system, as claimed in claim 1, wherein:
said two pairs of columns extend at a non-vertical angle from a surface upon which the columns are mounted.

3. A system, as claimed in claim 1, wherein:
said first and second cables have a first curvature, and said complementary support cable has a second different curvature.

4. A system, as claimed in claim 1, wherein:
each panel receiver includes a plurality of curved struts.

5. A system, as claimed in claim 1, wherein:
each panel receiver includes a plurality of straight struts, and a plurality of orthogonally oriented struts connected to the straight struts.

6. A system, as claimed in claim 1, wherein:
said first columns are longer than said second columns.

7. A system, as claimed in claim 1, further including:
a plurality of anchor lines connected to said columns, and a plurality of anchors connected to said anchor lines for anchoring said anchor lines into the ground.

8. A system, as claimed in claim 1, further including:
a pair of cross-supports, one cross support interconnecting each said pair of columns.

9. A system, as claimed in claim 1, wherein:
said first and second columns of each said pair of columns are arranged in a V-shaped configuration such that lower ends of said first and second columns of each pair extend from a common mounting point, and upper ends of the first and second columns diverge from one another.

10. A system, as claimed in claim 7, wherein:
said anchor lines secured to each pair of columns extends to respective common mounting points on the surface to which the columns are mounted.

11. A system, as claimed in claim 1, wherein:
said system comprises a plurality of rows of solar panel arrays, each row being selectively spaced from an adjacent row, and said rows extending substantially parallel to one another.

12. A system, as claimed in claim 1, wherein:
at least one of said panel receivers includes a pivot mount enabling a solar panel mounted thereover to be rotated at a desired incident angle with the sun.

13. A system, as claimed in claim 1, wherein:
said at least one complementary support cable and said first or second cable are coplanar.

14. A system, as claimed in claim 1, wherein:
said at least one complementary support cable includes a pair of complementary support cables, a first complementary support cable being coplanar with said first cable, and the other complementary support cable being coplanar with the second cable.

15. A system, as claimed in claim 1, wherein:
said plurality of panel receivers have a first end residing at a first height, and a second end residing at a second lower height, wherein said plurality of panel receivers are substantially rectangular shaped and evenly spaced from one another along said first and second cables.

16. A system, as claimed in claim 1, wherein:
said first cable defines a first curvature, said second cable defines a second curvature extending substantially parallel to said first curvature, and wherein said gap is substantially triangular shaped such that the gap located adjacent the second cable is smaller than the gap located adjacent the first cable.

17. A system for supporting a solar panel array, said system comprising:
two pairs of columns, each pair having a first column and a second column;
a first cable suspended between first columns, said first cable having a first curvature;
a second cable suspended between the second columns, the second cable having a second curvature substantially parallel to the first curvature;
a plurality of panel receivers each having a plurality of solar panels mounted thereto, said panel receivers each having a number of curved struts, said curved struts extending along a third curvature, said curved struts having ends that connect to said first and second cables, and wherein said third curvature of said curved struts intersects said first and second curvatures of said first and second cables at or adjacent to locations where said panel receivers mount to said first and second cables.

18. A method of supporting a plurality of solar panels, said method comprising the steps of:
providing a plurality of pairs of columns, each pair having columns of dissimilar heights extending above a surface to which the columns are mounted;
spacing the columns apart from one another;
extending a first and second cable between the two pairs of columns, the first cable suspended at a first height, and the second cable suspended at a second different height; and
attaching a plurality of panel receivers to said first and second cables, said plurality of panel receivers each having a plurality of solar panels mounted thereto, said panel receivers being disposed at a non-vertical angle with respect to a surface upon which the columns are mounted, and said plurality of panel receivers being spaced from one another along said cables by a gap having a width less than a width of said panel receivers.

19. A method, as claimed in claim 18, wherein:
each panel receiver includes at least one of a plurality of curved struts, a plurality of straight struts, or combinations thereof.

20. A method, as claimed in claim 18, further comprising:
stabilizing said system by providing a plurality of anchor lines secured to selected ones of said columns, said anchor lines each having an end secured to the mounting surface.

21. A method, as claimed in claim 18, wherein:
said solar panels are angularly mounted to said panel receivers, and selectively rotated to a desired angle optimizing exposure of the solar panels to the sun.

22. A method, as claimed in claim 18, wherein:
said panel receivers are provided in a plurality of rows each supported by a corresponding combination of columns and cables;
said rows being selectively spaced from one another; and
said plurality of rows extending substantially parallel to one another.
